(19) United States
(12) Patent Application Publication
(10) Pub. No.: US 2026/0090308 A1
(43) Pub. Date: Mar. 26, 2026

(54) PLASMA DICING WITH A PHOTO PATTERNABLE MATERIAL

(71) Applicant: TEXAS INSTRUMENTS INCORPORATED, DALLAS, TX (US)

(72) Inventors: DAIKI KOMATSU, BEPPU-SHI OITA-KEN (JP); HIROYUKI SADA, BEPPU-SHI OITA-KEN (JP); MASAMITSU MATSUURA, BEPPU-SHI OITA-KEN (JP); MAO SUGENO, BEPPU-SHI OITA-KEN (JP)

(21) Appl. No.: 18/898,029

(22) Filed: Sep. 26, 2024

(51) Int. Cl. H01L 23/00; H01L 21/56; H01L 21/683; H01L 21/78; H01L 23/31

(52) U.S. Cl. CPC H10P 54/00; H10W 70/415; H10W 70/417; H10P 72/7402; H10W 72/01351; H10W 72/01365; H10W 72/884; H10W 90/736; H10W 90/756

(57) ABSTRACT

Systems and methods plasma dicing are provided. The method includes forming a mask layer on a first surface of a wafer. The mask layer includes scribe lines and the wafer is diced along the scribe lines. The method also includes forming a die attach layer of a photo patternable material on a second surface of the wafer opposite the first surface. The method further includes patterning the die attach layer to form a number of openings in the die attach layer in a predetermined pattern. The method yet further includes applying a dicing tape to the die attach layer. The method includes dicing the wafer along the scribe lines to form dies of a plurality of dies supported by the dicing tape, a die of the plurality of dies having the die attach layer of the photo patternable material.

### TECHNICAL FIELD

This description relates to the use of a photo patternable material as a die attach material for plasma dicing.

### BACKGROUND

Semiconductor devices are fabricated on substrates in the form of thin wafers. Silicon is commonly used as the substrate material. After fabrication on the substrate, the individual devices (e.g., dies, chips, etc.) are typically separated from each other prior to packaging or being employed in other electronic circuitry. For many years, mechanical means have been used to separate the dies from each other. Such mechanical means have included breaking the wafer along scribe lines aligned with the substrate crystal axis or by using a high-speed diamond saw to saw into or through the substrate in a region (i.e., streets) between the dies. More recently, lasers have also been used to facilitate the scribing and dicing process. However, mechanical and laser techniques can cause chipping and breakage along the die edges, which can reduce the number of dies produced. Moreover, the process becomes more problematic as wafer thicknesses decrease. The area consumed by the saw bade (i.e., kerf) may be greater than 100 microns which is valuable area not useable for die production.

### SUMMARY

A first example is related to a method of plasma dicing with a photo patternable material. The method includes forming a mask layer on a first surface of a wafer. The mask layer includes scribe lines and the wafer is diced along the scribe lines. The method also includes forming a die attach layer of a photo patternable material on a second surface of the wafer opposite the first surface. The method further includes patterning the die attach layer to form a number of openings in the die attach layer in a predetermined pattern. The method yet further includes applying a dicing tape to the die attach layer. The method includes dicing the wafer along the scribe lines to form dies of a plurality of dies supported by the dicing tape, a die of the plurality of dies having the die attach layer of the photo patternable material.

A second example is related to a method of forming a semiconductor device. The method includes forming a mask layer on a first surface of a wafer. The mask layer includes scribe lines and the wafer is diced along the scribe lines. The method also includes forming a die attach layer of a photo patternable material to a second surface of the wafer opposite the first surface. The method further includes applying a photomask to the die attach layer. The photomask includes a number of photo portions corresponding to a wire bond pad on the interconnect. The method yet further includes patterning the die attach layer to form the number of openings in the die attach layer in a predetermined pattern based on the photomask. The method includes applying a dicing tape to the die attach layer. The method also includes dicing the wafer along the scribe lines to form dies of a plurality of dies supported by the dicing tape, a die of the plurality of dies having the die attach layer of the photo patternable material.

A third example is related to a semiconductor device. The semiconductor device includes a die attach layer of a photo patternable material having a number of openings in a predetermined pattern. The semiconductor device also includes a die affixed to an interconnect by the die attach layer. The semiconductor device further includes a bond wire that forms an electrical connection between the interconnect and the die.

### BRIEF DESCRIPTION OF THE DRAWINGS

FIG. 1 illustrates a cross-sectional view of an example of a semiconductor device.

FIG. 2 illustrates a top-view of an example wafer having a mask layer that includes scribe lines.

FIG. 3A illustrates a top-view of an example wafer having a die attach layer of a photo patternable material.

FIG. 3B illustrates a top-view of an example die of a wafer having a die attach layer of a photo patternable material.

FIG. 4 illustrates fine patterning of an example photo patternable material.

FIGS. 5-19 illustrate example stages of a method of plasma dicing an example of dicing a wafer having a photo patternable layer.

FIG. 20 illustrates a flowchart of an example method for fabricating an IC device with die attach layer of a photo patternable material.

### DETAILED DESCRIPTION

Recently plasma etching techniques have been proposed as a means of separating die to overcome the limitations of mechanical and laser dicing techniques. Some wafer structures however contain at least one composite layer that can be difficult to plasma etch without damaging the device. For example, the composite layer is a standard adhesive dimension (DAF). Standard DAFs are adhesive layers that can be used to bond chips to one another. However, the die attach material of standard DAFs is resistant to plasma etching. Accordingly, while the wafer may be severed during plasma etching, the DAF may not be severed. Thus, the severed wafer structures remain strung together by the DAF, making it difficult to pick the wafer structures from a lower support film, thereby lowering subsequent pick-up efficiency. Additionally, as wafers become thinner, low pick-up efficiency is further exacerbated, causing increasing chipping and/or breakage, further lowering yield.

Here, the die attach layer is formed of a photo patternable material rather than the standard DAF material in order to improve pick-up efficiency and reduce chipping and breakage. The photo patternable material is etched at approximately the rate that the wafer is etched, reducing cracking and/or breakage of the wafer and simplifying the manufacturing process. Furthermore, the photo patternable material is patterned to reduce pattern bleed out of the photo patternable material caused by the wafer being affixed to the interconnect, thus improving reliability and efficiency of a semiconductor packaging process.

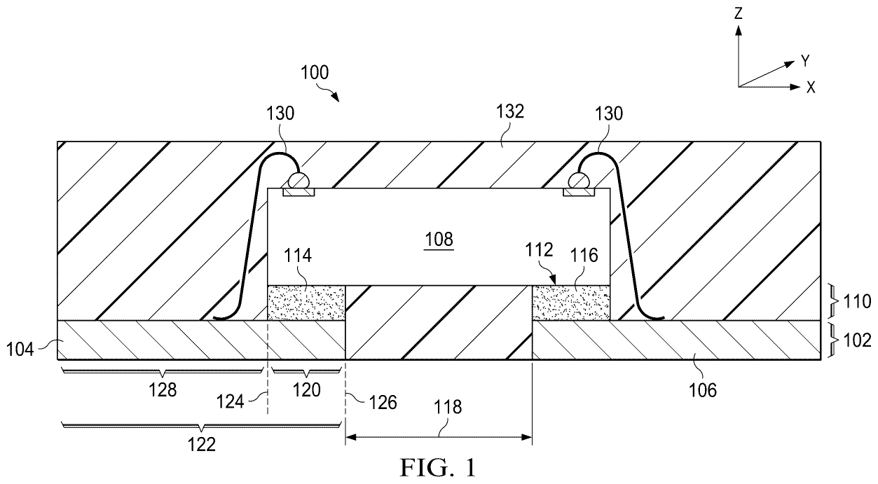

FIG. 1 illustrates an integrated circuit (IC) such as a chip on lead (COL) configuration of a semiconductor ready for packaging. The semiconductor device 100 includes an interconnect 102 having a number of interconnect locations. The interconnect locations include a first wire bond pad 104 and a second wire bond pad 106. The interconnect 102 is formed of an electrically conductive material, such as copper, palladium, gold, silver, or other appropriate conductive metal or metal alloy with similar properties. For example, the interconnect 102 is formed from a lead frame.

A die 108 has an die attach layer 110 at a surface portion 112 of the die 108. The die attach layer 110 bonds the die 108 to the interconnect locations. The die attach layer 110 is formed of a photo patternable material. In one example, the photo patternable material is a photo-patternable polymer films, such as any of a variety of SU-8 materials or polyimide materials, such as epoxy resin, polybenzoxazole, polyimide, benzocyclobutene, and combinations thereof. The photo-patternable material is patterned using similar photolithography methods as a photoresist material. The patterning causes the die attach layer 110 to be continuous or discontinuous. For example, the die attach layer 110 is discontinuous and includes a first adhesive section 114 and a second adhesive section 116 that are coplanar and separated by a gap distance 118 in a first direction. The gap distance 118 is the distance between the first wire bond pad 104 and the second wire bond pad 106. In particular, the gap distance 118 is the distance between an edge of the first wire bond pad 104 and the second wire bond pad 106 in the first direction.

The first adhesive section 114 has a first adhesive dimension 120 extending in a first direction, in one example, the x-direction. The first adhesive dimension 120 is less than a wire bond dimension 122 of the first wire bond pad 104. In one example, the gap distance 118 extends from a first edge 124 opposite a second edge 126 in the first direction. The first edge 124 is approximately collinear with an edge of the die 108 overlaying the die attach layer 110. The second edge 126 is approximately collinear with an edge of the first wire bond pad 104. The remaining portion of the wire bond dimension 122 of the first wire bond pad 104 has a remainder dimension 128 that corresponds to the length, in the first direction of the surface portion of the die 108 that is not overlayed by the first adhesive section 114. In some examples, the die attach layer 110 is continuous at the surface portion 112 of the die 108 from the first edge 124 to an opposite edge of the die 108 collinear with the second wire bond pad 106.

Bond wires 130 forms an electrical connection between the interconnect 102 and the die 108. For example, the bond wire 130 is attached at the die 108 and the second wire bond pad 106 and forms an electrical connection between the die 108 and the wire bond pad 106. The wire bond pads 104, 106, the die 108, the die attach layer 110, and the bond wire(s) 130 are at least partially encapsulated in a molding compound 132 to form a packaged semiconductor device 100, such as a COL semiconductor device.

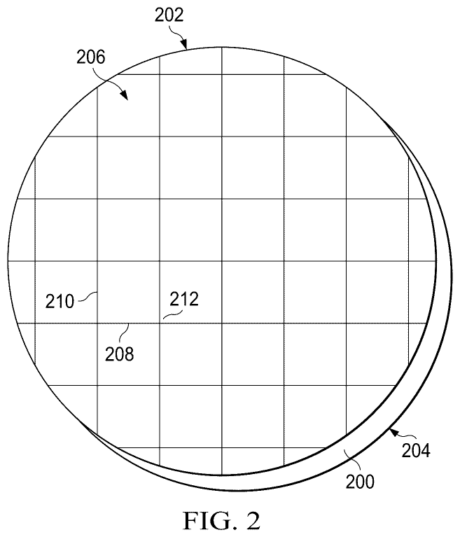

Dies, such as the die 108 of FIG. 1, are fabricated using photolithographic techniques on wafers. Turning to FIG. 2, a number of dies are fabricated on a wafer 200 having a first surface 202 opposite a second surface 204. The wafer 200 is a substrate, such as silicon, silicon carbide, or other suitable material, either in substantially pure form or in combination with additional materials. As another example, the wafer 200 is a single crystal material, such as a single crystal silicon substrate. As yet another example, the wafer 200 is a complementary metal-oxide semiconductor (CMOS) substrate and includes circuitry formed thereon.

The wafer 200 includes a mask layer 206 formed on the first surface 202. As one example, the mask layer 206 is a photoresist pattern having scribe lines that delineate the individual dies. For example, the scribe lines are formed using photolithography techniques. The scribe lines are openings in the mask layer 206 that expose the first surface 202 of the wafer 200. For example, the scribe lines extend in a first direction as horizontal scribe lines 208 and in a second direction, approximately orthogonal to the first direction, as vertical scribe lines 210. The horizontal scribe lines 208 and the vertical scribe lines 210 intersect at intersections 212 corresponding to the corners of individual dies. The horizontal scribe lines 208 and the vertical scribe lines 210 correspond to edges of the dies. The pattern of the scribe lines is based on geometry of the individual dies.

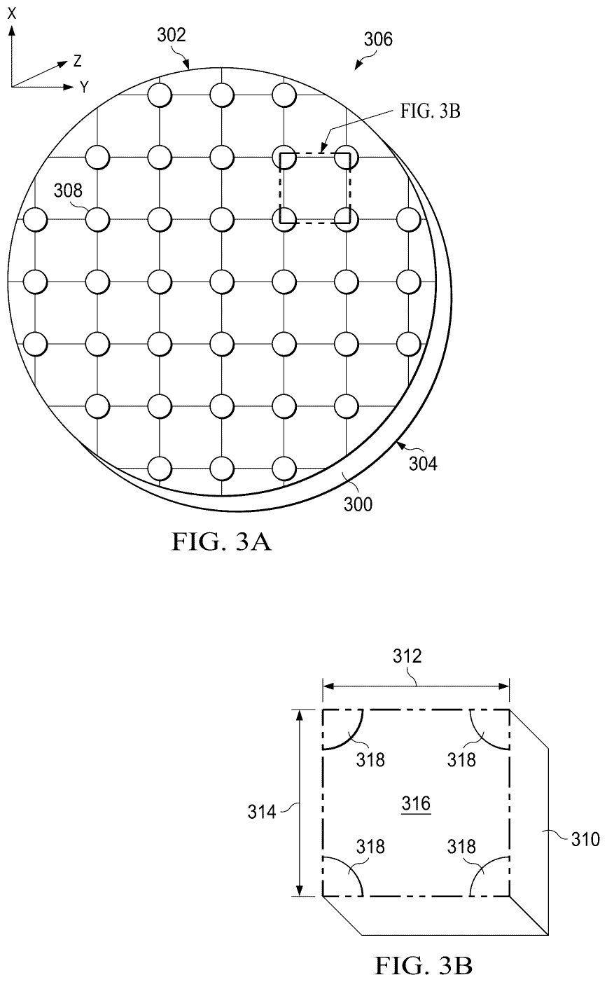

FIG. 3A illustrates a view of a wafer 300 (e.g., the wafer 200 of FIG. 2) having a first surface 302 (e.g., the first surface 202 of FIG. 2) opposite a second surface 304 (e.g., the second surface 204 of FIG. 2). The wafer 300 includes a die attach layer 306 of a photo patternable material to a second surface 304 of the wafer 300. The photo patternable material is a photo-imageable, bonding resist.

The die attach layer 306 is patterned with a number of photo patterned features. For example, the photo patterned features include openings 308 in the die attach layer 306 that expose the second surface 304 of the wafer 300. The openings 308 can be any shape (e.g., amorphous, circular, rectangular, etc.).

FIG. 3B illustrates a view of individual dies, such as a die 310 (e.g., the die 108 of FIG. 1) of the wafer 300. As one example, the openings 308 are patterned to correspond to the die 310. The die 310 has a first die dimension 312 extending in the x-direction and a second die dimension 314 extending in the y-direction approximately orthogonal to the x-direction. The first die dimension 312 and the second die dimension 314 define a die surface area in the x-y plane.

A die attach region 316 of the die attach layer 306 corresponds to the die 310. The die attach region 316 includes openings 308 and/or opening portions 318 in the photo patternable material. For example, the die attach region 316 has a first adhesive dimension extending in first die dimension 312 and a second adhesive dimension extending in the second die dimension 314. The first adhesive dimension and the second adhesive dimension are based on the first die dimension 312 and a second die dimension 314 of the die 310. The photo patternable surface area is the surface area of the die attach region 316 having photo patternable material. Accordingly, the photo patternable surface area is the die surface area less the surface area of the openings 308 and/or opening portions 318 in the photo patternable material. The die 310 defines a number of edges in the first die dimension 312 and the second die dimension 314. The number of openings 308 and/or opening portions 318 in the die attach region 316 of the die attach layer 306 are positioned to partially overlay an edge of the number of edges to reduce pattern bleed. For example, openings 308 and/or opening portions 318 in the die attach region 316 of the die attach layer 306 are positioned to partially overlay scribe lines (e.g., horizontal scribe lines 208, vertical scribe lines 210 of FIG. 2) to reduce pattern bleed because the scribe lines correspond to the edges of the die 310.

In some examples, the photo patternable surface area is less than the die surface area. The photo patternable surface area being smaller than the die surface area reduces the pattern bleed out of the photo patternable material when the die 310 is affixed to an interconnect (e.g., the interconnect 102 of FIG. 1) by reducing the footprint of the photo patternable material. In some examples, the number of openings 308 and/or opening portions 318 in the die attach layer 306 are positioned to partially overlay scribe lines (e.g., the horizontal scribe lines 208, vertical scribe lines 210 of FIG. 2) of the mask layer (e.g., the mask layer 206 of FIG. 2) to reduce pattern bleed.

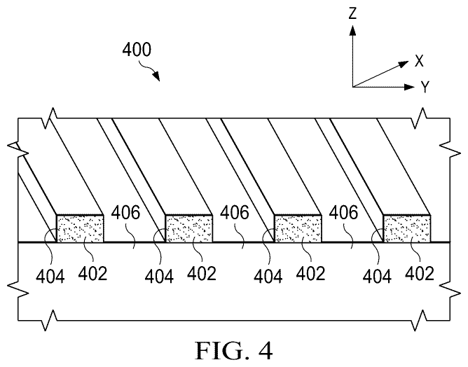

Additionally or alternatively, the number of photo patterned features include features that extend in the z-direction orthogonal to the x-y plane. For example, turning to FIG. 4, the photo patterned features of a die attach layer 400 (e.g., the die attach layer 110 of FIG. 1, the die attach layer 306 of FIG. 3A) include ridges 402 with sidewalls 404 extending in the z-direction separated by wells 406. Accordingly, the photo patternable surface area includes the surface area of the sidewalls 404 of the ridges 402. Because the die surface area is based on a second surface (e.g., the second surface 204 of FIG. 2, the second surface 304 of FIG. 3A) of the wafer (e.g., the wafer 200 of FIG. 2, the wafer 300 of FIG. 3A) in the x-y plane, the die attach layer 400 may have a greater surface area then the die surface area. The wells 406 reduce the pattern bleed out of the photo patternable material when the die (e.g., the die 108 of FIG. 1, the die 310 of FIG. 3B) is affixed to an interconnect (e.g., the interconnect 102 of FIG. 1) because the photo patternable material can flow into the wells 406 when the compressed.

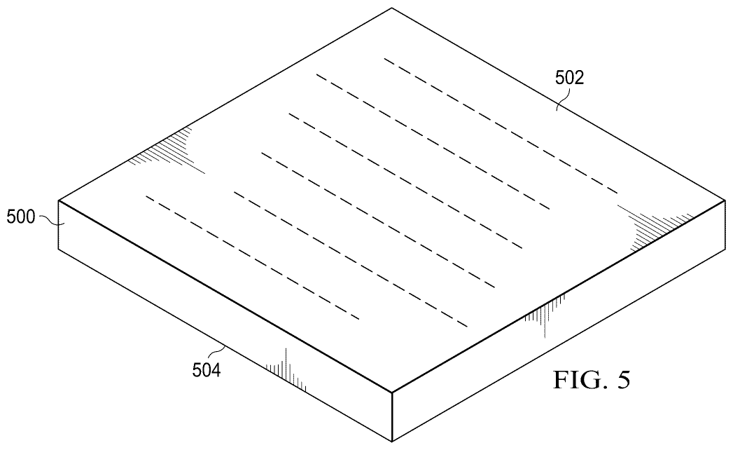

FIGS. 5-19 illustrate stages of a method for formation of a semiconductor ready for packaging, such as semiconductor device 100 of FIG. 1 with a die attach layer of a photo patternable material. For purposes of simplification, FIGS. 5-19 employ the same reference numbers to denote the same structure.

FIG. 5 illustrates an example of a first stage of a method of forming the semiconductor ready for packaging. For example, FIG. 5 illustrates an example of a wafer 500 (e.g., the wafer 200 of FIG. 2, the wafer 300 of FIG. 3A) having a first surface 502 (e.g., the first surface 202 of FIG. 2, the first surface 302 of FIG. 3A) opposite a second surface 504 (e.g., the second surface 204 of FIG. 2, the second surface 304 of FIG. 3A). The formation of the wafer 500 is dependent on the application of the semiconductor device (e.g., the semiconductor device 100 of FIG. 1) being fabricated.

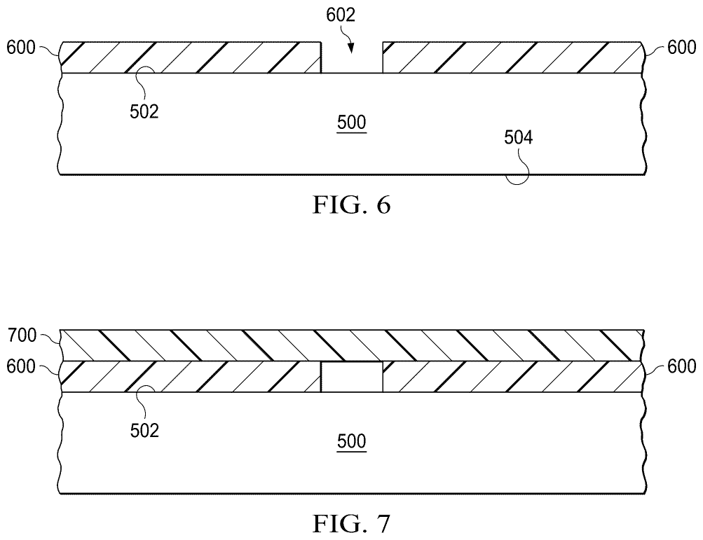

FIG. 6 illustrates an example of a second stage of the method. In the second stage, a mask layer 600 (e.g., the mask layer 206 of FIG. 2) is formed on the first surface 502 of the wafer 500. The mask layer 600 is patterned to include scribe lines 602. As one example, the scribe lines 602 (e.g., the horizontal scribe lines 208, the vertical scribe lines 210 of FIG. 2) are formed by etching the mask layer 600.

A patterned photoresist (not shown) is applied to the mask layer 600. The nonirradiated portions of the mask layer 600 are removed by applying a developer material. For example, a dry etch is performed on the mask layer 600 to form the scribe lines 602 corresponding to the voids in the patterned photoresist. The scribe lines 602 in the mask layer 600 indicate individual dies of the plurality of dies in the wafer 500. Accordingly, the area of the wafer 500 that is overlayed by scribe lines 602 does not include circuit elements of the dies such that the dies can be singulated along the scribe lines 602.

In some examples, the initial wafer thickness of the wafer 500, defined by the distance between the first surface 502 and the second surface 504, is adjusted by back grinding. In a third stage, as shown in FIG. 7, a back grinding tape 700 is applied to the mask layer 600. The back grinding tape 700 supports the wafer 500 during back grinding. Additionally, the back grinding tape 700 can act as a layer for protecting the mask layer 600 as well as the first surface 502 of the wafer 500 during back grinding.

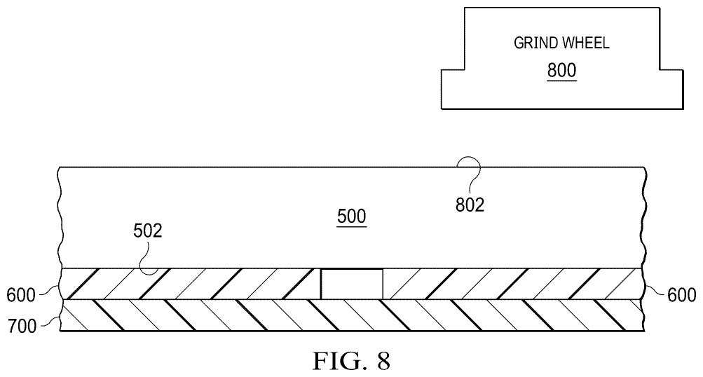

Turning to the fourth stage illustrated in FIG. 8, the second surface 504 of the wafer 500 is grinded with a grinding tool 800 to remove material from the second surface 504 forming an adjusted second surface 802. An adjusted wafer thickness is defined as the distance between the first surface 502 and the adjusted second surface 802. The adjusted wafer thickness is less thick than the initial wafer thickness since wafer material is removed.

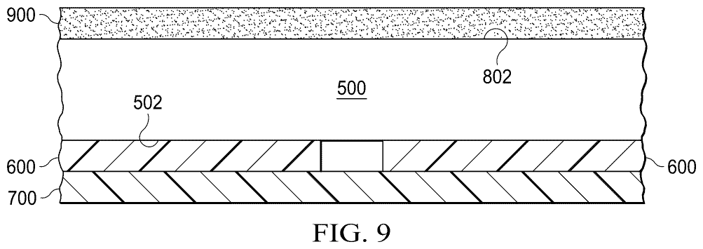

FIG. 9 illustrates an example of a fifth stage of the method. In the fifth stage, a die attach layer 900 (e.g., the die attach layer 110 of FIG. 1, the die attach layer 306 of FIG. 3A, the die attach layer 400 of FIG. 4) of a photo patternable material to the adjusted second surface 802 of the wafer 500 opposite the first surface 502. As an example, the photo patternable material of the die attach layer 900 may be any of a variety of photo-patternable polymer films, such as any of a variety of SU-8 materials or polyimide materials. The photo patternable material may be deposited using a spin-on coating process to form the die attach layer 900.

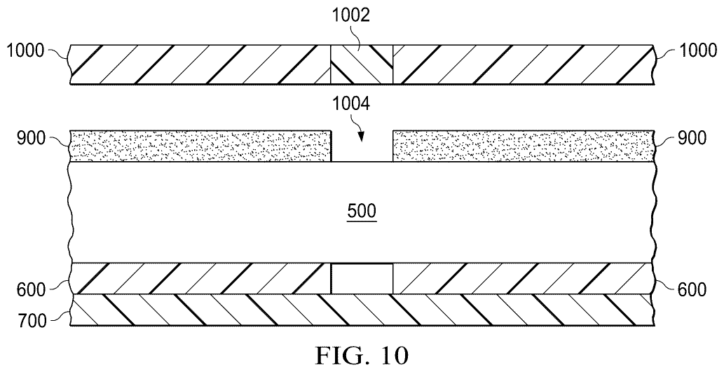

FIG. 10 illustrates an example of a sixth stage of the method. In the sixth stage, the die attach layer 900 is patterned to form a number of photo patterned features (e.g., the openings 308 and the opening portions 318 of FIG. 3B, the ridges 402 of FIG. 4). For example, the die attach layer 900 is patterned with openings in the die attach layer 900 in a predetermined pattern.

In some examples, the die attach layer 900 is patterned by a performing selective irradiation with a photomask 1000. The photomask 1000 is applied to the die attach layer 900. The photomask 1000 includes a photo portion 1002. In some examples, the photo portion 1002 is opaque such that the portion of the die attach layer 900 is blocked by the opacity of the photo portion 1002 and is not irradiated. The irradiated or nonirradiated portions of the die attach layer 900 are removed by applying a developer material. For example, a dry plasma etch is performed on the to remove the nonirradiated portion from the die attach layer 900 to form the predetermined pattern based on the photomask including one or more photo patternable features, such as the photo patternable feature 1004. The dry plasma etch is based on the type of material forming the wafer 500 and the photo patternable material. For example, the plasma etch is a fluorine-based plasma etch and the feature tool is a parallel plate Reactive Ion Etch apparatus, Inductively Coupled Plasma reactor or, alternatively, an electron cyclotron resonance plasma reactor.

In some examples, the photomask 1000 includes a number of photo portions 1002 corresponding to a wire bond pad (e.g., the wire bond pads 104, 106 of FIG. 1) of an interconnect (e.g., the interconnect 102 of FIG. 1). For example, the photo portion 1002 is positioned so that an opening is formed at a location corresponding to a second edge (e.g., the second edge 126 of FIG. 1) is approximately collinear with an edge of the first wire bond pad (e.g. the first wire bond pad 104 of FIG. 1). In another example, the photo portion 1002 is positioned so that an opening is formed between a first edge (e.g., the first edge 124) and the second edge to prevent bleed. In some examples, the opening does not meet or exceed the first edge and/or the second edge. Thus, the photomask 1000 is used to pattern the die attach layer 900 based on the future placement of the die relative to the wire bond pads.

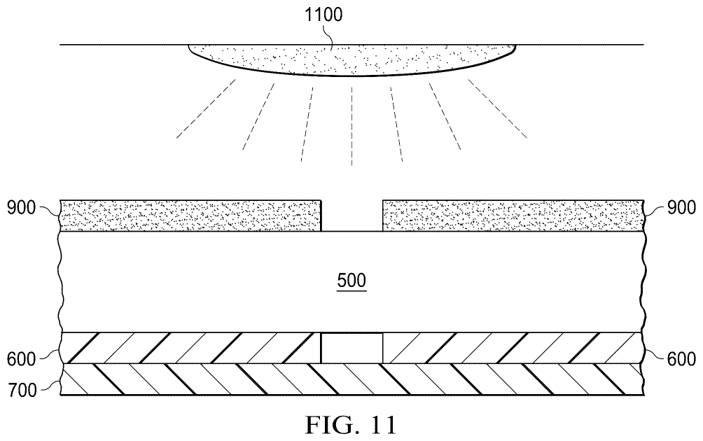

FIG. 11 illustrates an example of a seventh stage of the method. In the seventh stage the, the die attach layer 900 undergoes a cure causing the die attach layer 900 to become sticky or tacky. For example, during the cure, a curing apparatus 1100 applies energy to the die attach layer 900. In one example, the curing apparatus 1100 is a heat source that heats the die attach layer 900. The curing apparatus 1100 heats the die attach layer 900 to a temperature of approximately 150° C. In another example, the curing apparatus 1100 is an ultraviolet (UV) source that irradiates the die attach layer 900.

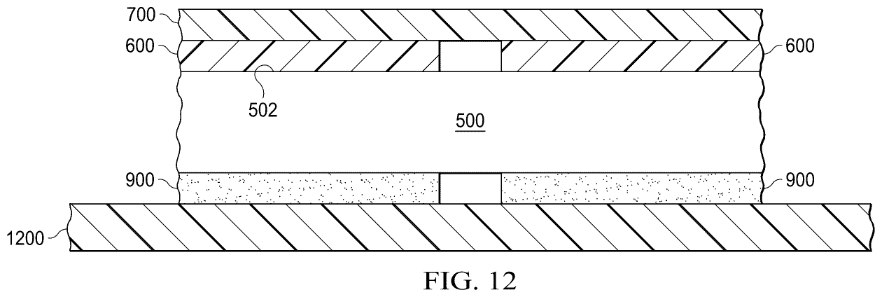

FIG. 12 illustrates an example of an eighth stage of the method. In the eighth stage, the wafer 500 is affixed to dicing tape 1200 using the die attach layer 900. The die attach layer 900 bonds the wafer 500 to the dicing tape 1200 to support the dies during and after singulation. In some examples, the dicing tape 1200 acts as an etch stop layer during plasma etching.

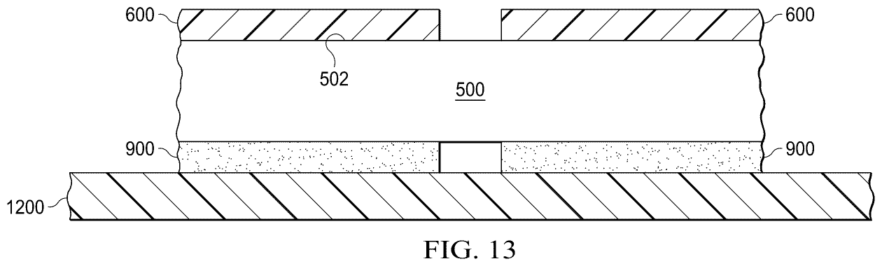

FIG. 13 illustrates an example of a ninth stage of the method. In the ninth stage, the back grinding tape 700 is removed from the mask layer 600.

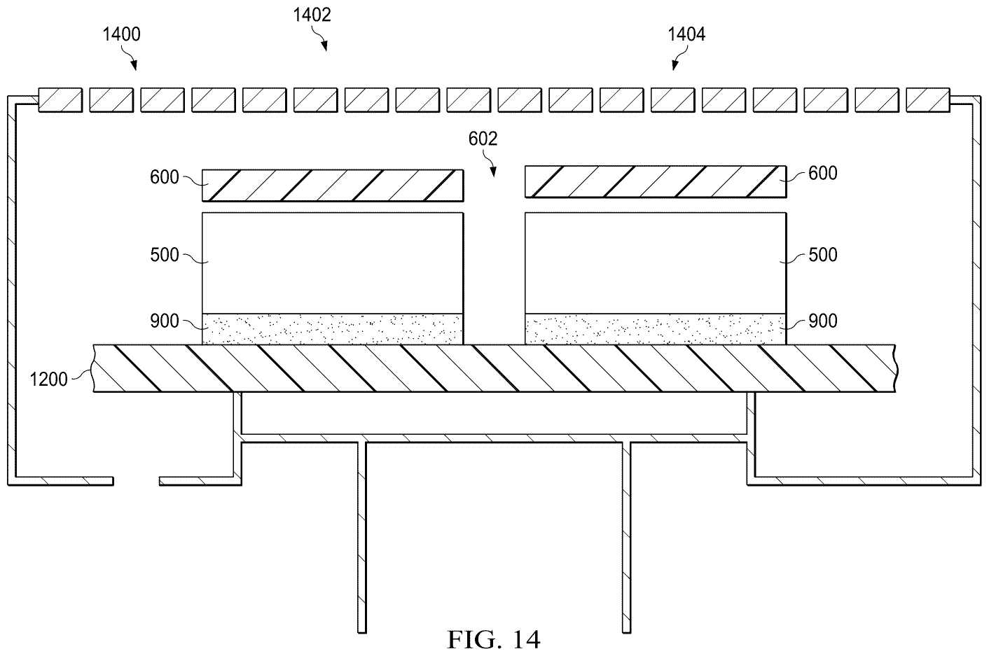

FIG. 14 illustrates an example of a tenth stage of the method. In the tenth stage, the wafer 500 is plasma diced into a plurality of dies (e.g., the die 108 of FIG. 1, the die 310 of FIG. 3B) including a first die 1402 and a second die 1404. The plasma dicing uses plasma etching techniques to singulate the first die 1402 and the second die 1404. The dies 1402, 1404 include material of the wafer 500 and the die attach layer 900.

The plasma etching techniques include placing the wafer 500 in a dicing chamber 1400. The dicing chamber 1400 may be a vacuum chamber fitted with a high-density plasma source such as inductively coupled plasma (ICP). A plasma is created in the dicing chamber 1400 by exciting ions in an etch gas having a gas chemistry based on the material of the wafer 500. For example, the etch gas includes a halogen (e.g., fluorine, chlorine, bromine, or iodine) or halogen-containing gas. In response to the reaction between the plasma and the portions of the wafer 500 exposed by the scribe lines 602, material of the wafer 500 and the underlying die attach wafer 500 are removed such that individual dies 1402, 1404 are singulated from the wafer 500. The plasma etch having a gas chemistry is performed to remove portions of the wafer 500 and the die attach layer 900. The gas chemistry is selected to etch the photo patternable material of the die attach layer 900 at approximately the rate that the wafer 500 is etched, reducing cracking and/or breakage of the wafer 500.

Additionally, the mask layer 600 may be removed from the first surface 502 of the wafer 500 during plasma dicing. For example, the mask layer 600 is removed by a strip process or an ashing process during plasma etching. Alternatively, the mask layer 600 is removed prior to plasma dicing or after plasma dicing.

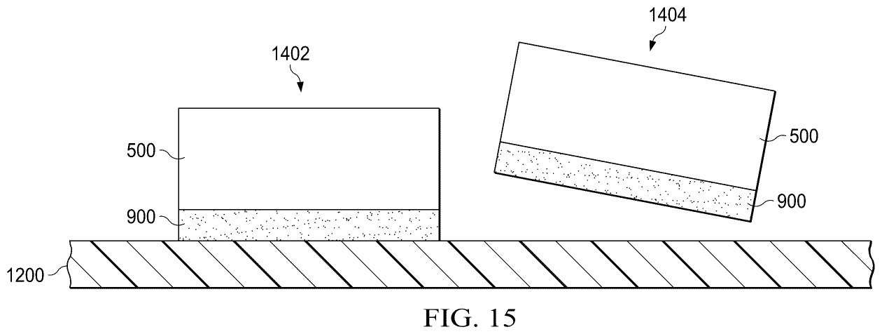

FIG. 15 illustrates an example of an eleventh stage of the method. In the eleventh stage, the individual dies 1402, 1404 are released from the dicing tape 1200. For example, the second die 1404 is pushed from the dicing tape 1200 with a pin during an example pick-up process. As another example, the dicing tape 1200 is drawn away from the dies 1402, 1404 by vacuum in another example pick-up process. The first die 1402 and the second die 1404 include the wafer 500 and the die attach layer 900.

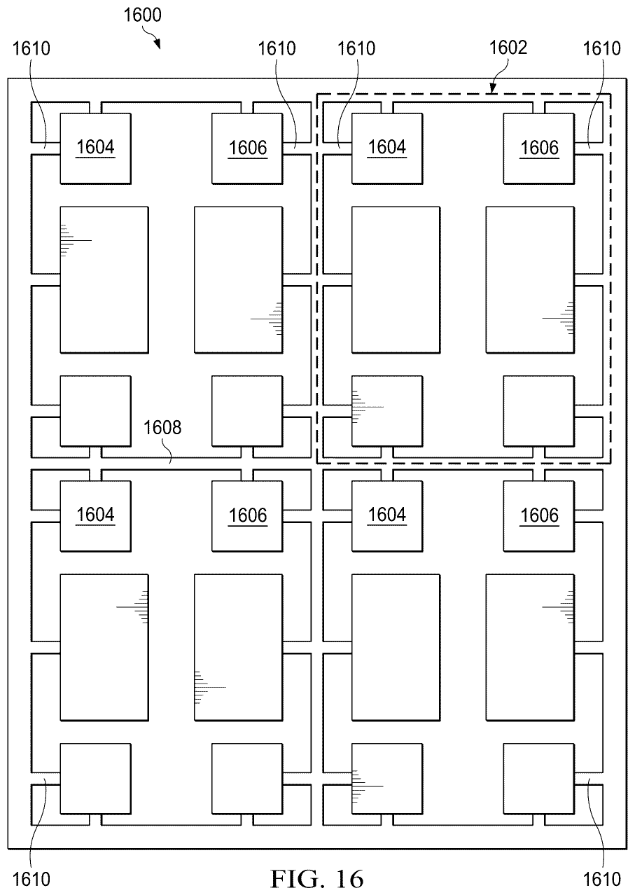

FIG. 16 illustrates an example of a twelfth stage of the method. In the twelfth stage, an interconnect 1600 (e.g., the interconnect 102 of FIG. 1) is provided. The interconnect 1600 is formed of an electrically conductive material, such as copper, palladium, gold, silver, or other appropriate conductive metal or metal alloy with similar properties. For example, the interconnect is formed from a copper lead frame. As one example, the interconnect 1600 accommodates multiple dies (e.g., the first die 1402, the second die 1404 of FIG. 14). An interconnect area 1602 is configured to accommodate a single die.

For a chip on lead configuration of a semiconductor, the interconnect area 1602 has wire bond pads (e.g., the first wire bond pad 104, the second wire bond pad 106 of FIG. 1) including a first wire bond pad 1604 and a second wire bond pad 1606 that are electrically isolated from each other. For other configurations of a semiconductor device, the interconnect 1600 includes a wire bond pad directly under the die. The wire bond pads 1604, 1606 are typically connected to saw streets 1608 with tie bars 1610. The saw streets 1608 and the tie bars 1610 are formed of thin metal strips. The saw streets 1608 support the interconnect 1600 during die attach (IC chip attachment to the interconnect), wire bonding (wire connecting IC bond pads to wire bond pads), and potting (encapsulation of the IC chip, wire bonds, and interconnects 1600 with mold compound).

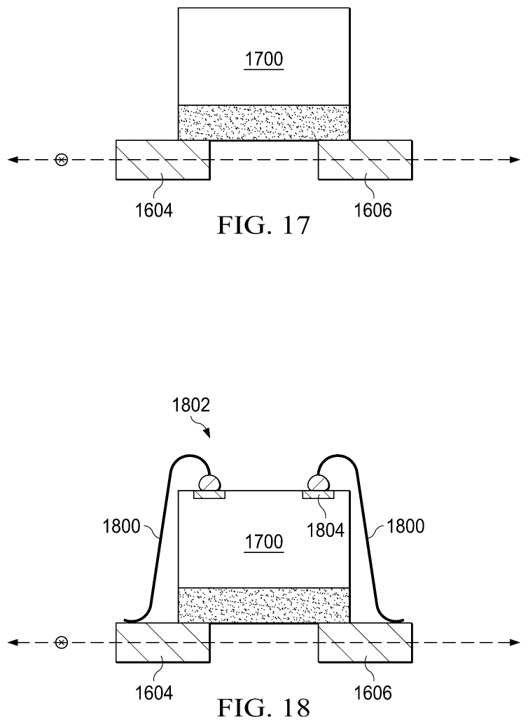

FIG. 17 illustrates an example of a thirteenth stage of the method. For clarity, the remaining stages will be shown and described with respect to a single die and a portion of the interconnect area 1602. In the thirteenth stage, a die 1700 (e.g., the die 108 of FIG. 1, the die 310 of FIG. 3B, the first die 1402, the second die 1404 of FIG. 14) is mounted on the wire bond pads 1604, 1606. The die 1700 is mounted using the photo patternable material of the die attach layer 900 to affix the die 1700 to the interconnect area 1602.

FIG. 18 illustrates an example of a fourteenth stage of the method. In the fourteenth stage, a bond wire 1800 (e.g., the bond wire 130 of FIG. 1) is attached at the die 1700 and the wire bond pads 1604, 1606 resulting in a semiconductor device 1802. The bond wire 1800 forms an electrical connection between the die 1700, at a first landing pad 1804, and the second wire bond pad 1606.

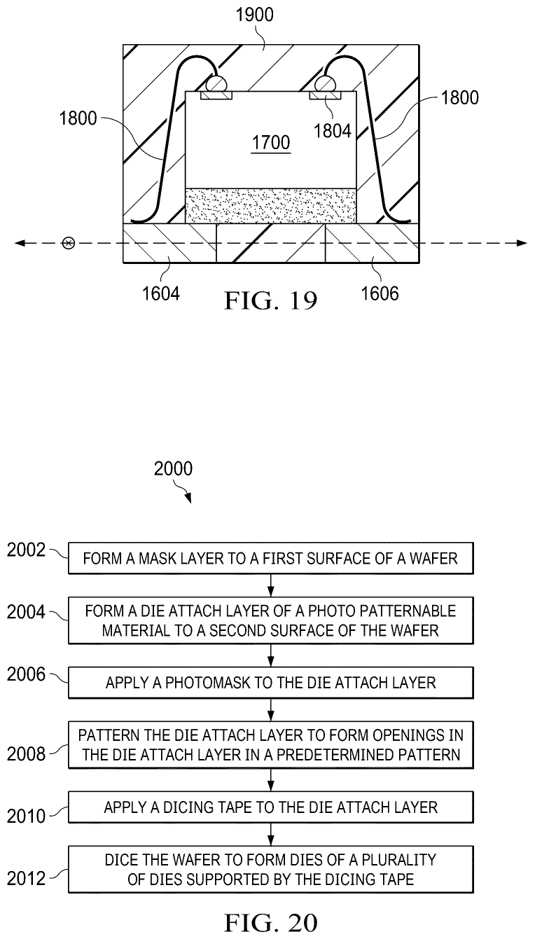

FIG. 19 illustrates an example of a fifteenth stage of the method. In the fifteenth stage, the semiconductor device 1802 is encapsulated in a mold compound 1900 (e.g., the mold compound 132 of FIG. 1). The mold compound 1900 is formed of one or more insulating material, such as organic resins (e.g., epoxy), inorganic resins, and/or other suitable materials. The mold compound 1900 at least partially encapsulates the die 1700, the wire bond pads 1604, 1606, and the bond wire 1800.

FIG. 20 illustrates a flowchart of an example method for fabricating an IC device with die attach layer of a photo patternable material. At block 2002, the method 2000 includes forming a mask layer (e.g., the mask layer 206 of FIG. 2, the mask layer 600 of FIG. 6) to a first surface (e.g., the first surface 202 of FIG. 2, the first surface 302 of FIG. 3A, the first surface 502 of FIG. 5) of a wafer (e.g., the wafer 200 of FIG. 2, the wafer 300 of FIG. 3A, the wafer 500 of FIG. 5). The mask layer includes scribe lines (e.g., the horizontal scribe lines 208, vertical scribe lines 210 of FIG. 2, the scribe lines 602 of FIG. 6).

At block 2004, the method 2000 includes forming a die attach layer (e.g., the die attach layer 306 of FIG. 3A, the die attach layer 400 of FIG. 4, the die attach layer 900 of FIG. 9) of a photo patternable material to a second surface (e.g., the second surface 204 of FIG. 2, the second surface 304 of FIG. 3A, the second surface 504 of FIG. 5) of the wafer opposite the first surface.

At block 2006, the method 2000 includes applying a photomask (e.g., the photomask 1000 of FIG. 10) to the die attach layer. The photomask includes a number of photo portions (e.g., the photo portions 1002 of FIG. 10) corresponding to a wire bond pad (e.g., first wire bond pad 104, the second wire bond pad 106 of FIG. 1, the first wire bond pad 1604, the second wire bond pad 1606 of FIG. 16) of the interconnect (e.g., the interconnect 102 of FIG. 1, the interconnect 1600 of FIG. 16).

At block 2008, the method 2000 includes patterning the die attach layer to form the number of photo patterned features (e.g., the openings 308 and the opening portions 318 of FIG. 3B, the ridges 402 of FIG. 4) in the die attach layer in a predetermined pattern based on the photomask.

At block 2010, the method 2000 includes applying a dicing tape (e.g., the dicing tape 1200 of FIG. 12) to the die attach layer.

At block 2012, the method 2000 includes dicing the wafer along the scribe lines to form a die (e.g., the die 108 of FIG. 1, the die 310 of FIG. 3B, the first die 1402, the second die 1404 of FIG. 14, the die 1700 of FIG. 17) of a plurality of dies supported by the dicing tape. A die of the plurality of dies having the die attach layer of the photo patternable material. For example, the dicing is performed with a plasma etch. The photo patternable material of the die attach layer is etched at approximately the rate that the wafer is etched. Thus, the wafer and the die attach layer are etched with the same configuration to sever the wafer and the die attach layer. Accordingly, using a photo patternable material for the die attach layer reduces cracking and/or breakage of the wafer and simplifies the manufacturing process. Furthermore, the photo patternable material may be patterned to reduce pattern bleed out of the photo patternable material caused by the wafer being affixed to the interconnect, thus improving reliability and efficiency of a semiconductor packaging process.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

In this description, unless otherwise stated, “about,” “approximately” or “substantially” preceding a parameter means being within +/−10 percent of that parameter. Modifications are possible in the described embodiments, and other embodiments are possible, within the scope of the claims.

Further, unless specified otherwise, “first”, “second”, or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel. Additionally, “comprising”, “comprises”, “including”, “includes”, or the like generally means comprising or including, but not limited to.

It will be appreciated that several of the above-disclosed and other features and functions, or alternatives or varieties thereof, may be desirably combined into many other different systems or applications. Also, that various presently unforeseen or unanticipated alternatives, modifications, variations or improvements therein may be subsequently made by those skilled in the art which are also intended to be encompassed by the following claims.

What is claimed is:

1. A method of forming an integrated circuit (IC) comprising:
forming a mask layer on a first surface of a wafer, wherein the mask layer includes scribe lines;
forming a die attach layer of a photo patternable material on a second surface of the wafer opposite the first surface;
patterning the die attach layer to form a number of openings in the die attach layer in a predetermined pattern;
applying a dicing tape to the die attach layer; and
dicing the wafer along the scribe lines to form dies of a plurality of dies supported by the dicing tape, a die of the plurality of dies having the die attach layer of the photo patternable material.

2. The method of claim 1, wherein a die attach region of the die attach layer corresponds to the die of the plurality of dies, each die attach region having an opening of the number of openings.

3. The method of claim 2, wherein the die attach region of the die attach layer has a first adhesive dimension extending in a first direction and a second adhesive dimension extending in a second direction orthogonal to the first direction, and wherein the first adhesive dimension and the second adhesive dimension are based on a first die dimension and a second die dimension of the die.

4. The method of claim 2, wherein the die attach region has a photo patternable surface area and the die has a die surface area, and wherein the photo patternable surface area is less than the die surface area.

5. The method of claim 1, wherein the number of openings in the die attach layer are positioned to partially overlay scribe lines to reduce pattern bleed.

6. The method of claim 1, further comprising:
mounting a die of the dies to an interconnect by affixing the die attach layer of the photo patternable material to a surface of the interconnect;
affixing a bond wire from the die to the interconnect; and
encapsulating the die, the bond wire, and the interconnect in a mold compound.

7. The method of claim 1, further comprising:
applying a grinding tape to the mask layer; and
grinding the second surface of the wafer supported by the grinding tape.

8. The method of claim 1, further comprising:
curing the die attach layer to a temperature of approximately 150° C.

9. A method of forming a semiconductor device comprising:
forming a mask layer on a first surface of a wafer, wherein the mask layer includes scribe lines;
forming a die attach layer of a photo patternable material to a second surface of the wafer opposite the first surface;
applying a photomask to the die attach layer, wherein the photomask includes a number of photo portions corresponding to a wire bond pad on an interconnect;
patterning the die attach layer to form the number of openings in the die attach layer in a predetermined pattern based on the photomask;
applying a dicing tape to the die attach layer; and
dicing the wafer along the scribe lines to form dies of a plurality of dies supported by the dicing tape, a die of the plurality of dies having the die attach layer of the photo patternable material.

10. The method of claim 9, wherein a die attach region of the die attach layer corresponds to the die of the plurality of dies, each die attach region having an opening of the number of openings.

11. The method of claim 10, wherein the die attach region of the die attach layer has a first adhesive dimension extending in a first direction and a second adhesive dimension extending in a second direction orthogonal to the first direction, and wherein the first adhesive dimension and the second adhesive dimension are based on a first die dimension and a second die dimension of the die.

12. The method of claim 10, wherein the die attach region has a photo patternable surface area and the die has a die surface area, and wherein the photo patternable surface area is less than the die surface area.

13. The method of claim 9, wherein the number of openings in the die attach layer are positioned to partially overlay scribe lines to reduce pattern bleed.

14. The method of claim 9, further comprising:
mounting a die of the dies to the interconnect by affixing the die attach layer of the photo patternable material to a surface of the interconnect;
affixing a bond wire from the die to the interconnect; and
encapsulating the die, the bond wire, and the interconnect in a mold compound.

15. The method of claim 9, further comprising:
applying a grinding tape to the mask layer; and
grinding the second surface of the wafer supported by the grinding tape.

16. The method of claim 9, further comprising:
curing the die attach layer to a temperature of approximately 150° C.

17. A semiconductor device comprising:
a die attach layer of a photo patternable material having a number of openings in a predetermined pattern;
a die affixed to an interconnect by the die attach layer; and
a bond wire forms an electrical connection between the interconnect and the die.

18. The semiconductor device of claim 17, wherein the semiconductor device is chip on lead (COL) configuration, the interconnect includes a lead and the die is affixed to a portion of the lead and the bond wire forms the electrical connection between the lead and the die.

19. The semiconductor device of claim 17, wherein the die defines a number of edges, and wherein the number of openings in the die attach layer are positioned to partially overlay an edge of the number of edges to reduce pattern bleed.

20. The semiconductor device of claim 17 further comprising:
a molding compound that encapsulates the bond wire, the die attach layer, and the die.
